(19) United States
(12) Patent Application Publication
(10) Pub. No.: US 2017/0323795 A1
(43) Pub. Date: Nov. 9, 2017

(54) METHOD OF SELECTIVE ETCHING ON EPITAXIAL FILM ON SOURCE/DRAIN AREA OF TRANSISTOR

(71) Applicant: Applied Materials, Inc., Santa Clara, CA (US)

(72) Inventors: Xuebin LI, Sunnyvale, CA (US); Hua CHUNG, San Jose, CA (US); Flora Fong-Song CHANG, Saratoga, CA (US); Abhishek DUBE, Fremont, CA (US); Yi-Chiau HUANG, Fremont, CA (US); Schubert S. CHU, San Francisco, CA (US)

(21) Appl. No.: 15/585,016

(22) Filed: May 2, 2017

Related U.S. Application Data
(60) Provisional application No. 62/333,769, filed on May 9, 2016.

(51) Int. Cl. H01L 21/3065; H01L 29/66; H01L 29/08; H01L 21/67

(52) U.S. Cl. CPC H01L 21/3065; H01L 29/66795; H01L 21/67069; H01L 29/0843; H01L 29/66492

(57) ABSTRACT

Methods for forming transistors are provided. A substrate is placed in a processing chamber, and a plurality of epitaxial features is formed on the substrate. The epitaxial feature has at least a surface having the (110) plane and a surface having the (100) plane. An etchant or a gas mixture including an etchant and an etch enhancer or an etch suppressor is introduced into the processing chamber to remove a portion of the epitaxial feature. Etch selectivity between the surface having the (110) plane and the surface having the (100) plane can be tuned by varying the pressure within the processing chamber, the ratio of the flow rate of the etchant or gas mixture to the flow rate of a carrier gas, and/or the ratio of the flow rate of the etch enhancer or suppressor to the flow rate of the etchant.

### CROSS-REFERENCE TO RELATED APPLICATIONS

This application claims priority to U.S. Provisional Patent Application Ser. No. 62/333,769, filed on May 9, 2016, which herein is incorporated by reference.

### BACKGROUND

### Field

Embodiments described herein generally relate to methods for forming semiconductor devices, and more particularly to methods for forming transistors.

### Description of the Related Art

As circuit densities increase for next generation devices, the widths of interconnects, such as vias, trenches, contacts, gate structures and other features, as well as the dielectric materials therebetween, decrease to 22 nm or smaller dimensions, whereas the thickness of the dielectric layers remain substantially constant, with the result of increasing the aspect ratios of the features. Recently, complementary metal oxide semiconductor (CMOS) fin field effect transistor (FinFET) devices have been widely used in many logic and other applications and are integrated into various different types of semiconductor devices.

FinFET devices typically include semiconductor fins with high aspect ratios in which the channel and source/drain regions for the transistor are formed thereover. A gate electrode is then formed over and along side of a portion of the fin devices utilizing the advantage of the increased surface area of the channel and source/drain regions to produce faster, more reliable and better-controlled semiconductor transistor devices. Further advantages of FinFETs include reducing the short channel effect and providing higher current flow.

To improve transistor performance, stressor materials may fill source/drain areas, and the stressor materials may grow in source/drain areas by epitaxy. The epitaxial film may extend laterally and form facets. With the scaling down of transistors, fin pitch (distance between adjacent fins) is getting smaller. This may cause the reduction in the distance between an epitaxial film grown on a fin and an epitaxial film grown on an adjacent fin. Conventional etching process can increase the distance between the epitaxial film and the adjacent epitaxial film by removing a lateral dimension of the epitaxial film, but the thickness or height of the epitaxial film is also reduced by the etching process.

Processes for forming other types of transistors may include an etching process to remove a lateral dimension of a feature of the transistor, but the etching process also reduces the thickness or height of the feature.

Therefore, there is a need for an improved method for forming a transistor.

### SUMMARY

Methods for forming semiconductor devices, such as transistors, are provided. In one embodiment, a method includes placing a substrate having a plurality of epitaxial features into a processing chamber, wherein each epitaxial feature of the plurality of epitaxial features has at least a surface having a (110) plane and a surface having a (100) plane, heating the substrate to a temperature ranging from about 350 degrees Celsius to about 950 degrees Celsius, introducing an etchant and a carrier gas into the processing chamber, and selectively removing a portion of the epitaxial feature, wherein an etch selectivity between the surface having the (110) plane and the surface having the (100) plane is adjusted by varying a pressure within the processing chamber, and/or a ratio of a flow rate of the etchant to a flow rate of the carrier gas.

In another embodiment, a method includes placing a substrate having a plurality of epitaxial features into a processing chamber, wherein each epitaxial feature of the plurality of epitaxial features has at least a surface having a (110) plane and a surface having a (100) plane, heating the substrate to a temperature ranging from about 350 degrees Celsius to about 950 degrees Celsius, introducing a gas mixture and a carrier gas into the processing chamber, wherein the gas mixture includes an etchant and an etch enhancer or an etch suppressor, and selectively removing a portion of the epitaxial feature, wherein an etch selectivity between the surface having the (110) plane and the surface having the (100) plane is adjusted by varying a pressure within the processing chamber, a ratio of a flow rate of the gas mixture to a flow rate of the carrier gas, and/or a ratio of a flow rate of the etch enhancer or suppressor to a flow rate of the etchant.

In another embodiment, a method includes placing a substrate having a plurality of epitaxial features into a processing chamber, wherein each epitaxial feature of the plurality of epitaxial features has at least a surface having a (110) plane and a surface having a (100) plane, heating the substrate to a temperature of about 600 degrees Celsius or higher, introducing an etchant, a silicon containing gas, and a carrier gas into the processing chamber, and selectively removing a lateral portion of the epitaxial feature, wherein a height of the epitaxial feature is substantially unchanged.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a method for etching a feature according to one embodiment described herein.

FIGS. 2A-2C illustrate the feature according to various embodiments described herein.

FIGS. 3A-3B illustrate a process for forming a semiconductor structure according to one embodiment described herein.

FIGS. 4A-4B illustrate a process for forming a semiconductor structure according to another embodiment described herein.

FIGS. 5A-5B illustrate a process for forming a semiconductor structure according to another embodiment described herein.

FIGS. 6A-6F illustrate a process for forming a semiconductor structure according to another embodiment described herein.

FIGS. 7A-7E illustrate a process for forming a semiconductor structure according to another embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods for forming transistors are provided. A substrate is placed in a processing chamber, and a plurality of epitaxial features is formed on the substrate. The epitaxial feature has at least a surface having the (110) plane and a surface having the (100) plane. An etchant or a gas mixture including an etchant and an etch enhancer or an etch suppressor is introduced into the processing chamber to remove a portion of the epitaxial feature. Etch selectivity between the surface having the (110) plane and the surface having the (100) plane can be tuned by varying the pressure within the processing chamber, the ratio of the flow rate of the etchant or gas mixture to the flow rate of a carrier gas, and/or the ratio of the flow rate of the etch enhancer or suppressor to the flow rate of the etchant.

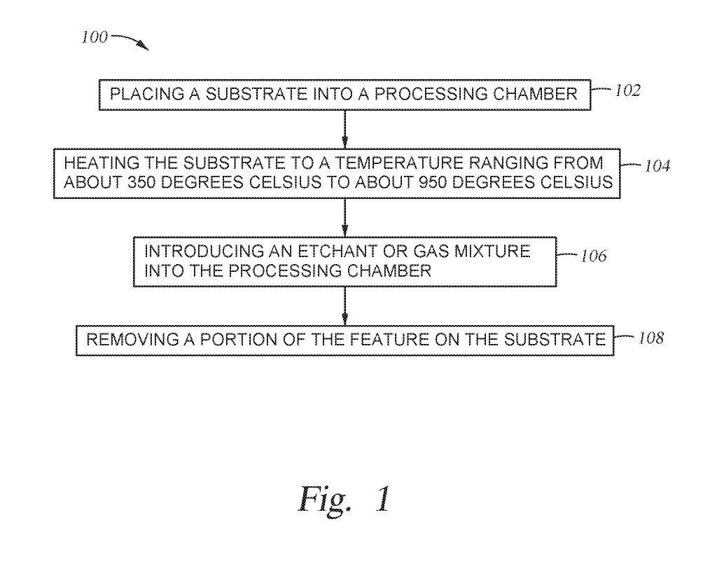

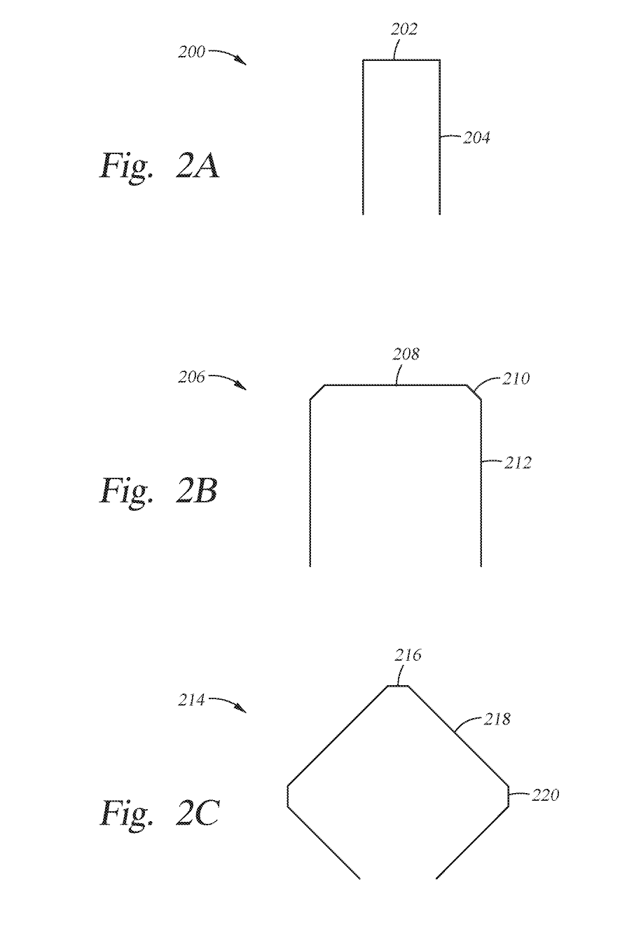

FIG. 1 illustrates a method 100 for etching a feature according to one embodiment described herein. The method 100 starts at block 102 which is placing a substrate into a processing chamber. A plurality of features may be formed on the substrate. The features may be formed on the substrate prior to placing the substrate into the processing chamber. Alternatively, the features may be formed on the substrate in the processing chamber. The processing chamber may be an epitaxial deposition chamber or an etch chamber. The substrate may be a bulk silicon substrate, and may be doped with a p-type or an n-type impurity. Other substrate materials include, but are not limited to, germanium, silicon-germanium, and group III/V compound semiconductors, such as GaAs, InGaAs, and other similar materials. The feature of the plurality of features may be a layer having an opening formed therein, a bar, a stressor material formed on a bar, or any other suitable feature. The feature includes at least a surface having the (110) plane and a surface having the (100) plane. The feature may be formed by an epitaxial deposition process, thus the features are referred to as epitaxial features. The feature may be made of silicon (Si), silicon germanium (SiGe), boron doped silicon germanium (SiGe:B), phosphorus doped silicon (Si:P), phosphorus doped germanium (Ge:P), or other suitable semiconductor material. Examples of the feature are shown in FIGS. 2A-2C.

As shown in FIG. 2A, a feature 200 includes at least a surface 202 and a surface 204. The surface 202 has the (100) plane and the surface 204 has the (110) plane. The surfaces 202, 204 may be connected to form a corner, and the corner may be 90 degrees. As shown in FIG. 2B, a feature 206 includes at least a surface 208 and a surface 212. The surface 208 has the (100) plane and the surface 212 has the (110) plane. A surface 210 connects the surface 208 and the surface 212, and the surface 210 has the (111) plane. As shown in FIG. 2C, a feature 214 includes at least a surface 216 and a surface 220. The surface 216 has the (100) plane and the surface 220 has the (110) plane. A surface 218 connects the surface 208 and the surface 212, and the surface 218 has the (111) plane.

Referring back to FIG. 1, at block 104, the substrate is heated to a temperature ranging from about 350 degrees Celsius to about 950 degrees Celsius. The substrate may be heated by any suitable heating device, such as radiant lamps, lasers, or resistive heating elements. The heating device may be located below and/or above the substrate or embedded in a substrate support supporting the substrate. In one embodiment, the substrate is heated to a temperature of about 600 degrees Celsius or higher, such as 700 degrees Celsius or 750 degrees Celsius. At block 106, an etchant or a gas mixture is introduced into the processing chamber. The etchant or the gas mixture is introduced into the processing chamber along with a carrier gas, such as hydrogen gas or nitrogen gas. The etchant may be a halogen containing gas, such as HCl, Cl₂, HBr, PCl₃, GeCl₃, BCl₃. The gas mixture may include the etchant and an etch enhancer or an etch suppressor. The etch enhancer may be GeH₄ or As. The etch suppressor may be a silicon containing gas, such as silane, disilane, or dichlorosilane. The etchant or the gas mixture may have a low partial pressure inside of the processing chamber. The low partial pressure of the etchant or the gas mixture may be reflected by the ratio of the flow rate of the etchant or the gas mixture to the flow rate of the carrier gas. The ratio may range from about 0.01 to about 0.22.

Next, at block 108, a portion of the feature is selectively removed by the etchant or the gas mixture. All of the surfaces of the feature, including the surfaces having (110) plane, surfaces having (100) plane, and surfaces having (111) plane, are exposed to the etchant or the gas mixture, and no masks or caps are formed on any of the surfaces of the feature. The portion of the feature that is removed by the etchant or the gas mixture can be controlled by tuning the etch selectivity between the surface having the (110) plane and the surface having the (100) plane. The etch selectivity between the surface having the (110) plane and the surface having the (100) plane can be expressed as the etch rate ratio of the surface having the (110) plane to the surface having the (100) plane, and the etch rate ratio can affect the portion of the feature that is removed. For example, if the etch rate ratio is high (i.e., higher etch rate on the surface having the (110) plane than the etch rate on the surface having the (100) plane), the lateral, or width, portion of the feature is removed while the height or thickness portion of the feature is substantially unchanged. Referring to FIGS. 2A-2C, with a high etch rate ratio, the surfaces 204, 212, 220 are removed at a faster rate than the surfaces 202, 208, 216. The surfaces having the (111) plane, such as surfaces 210, 218, have the slowest etch rate compared to the surfaces having the (110) or (110) plane. If the etch rate ratio is low (i.e., lower etch rate on the surface having the (110) plane than the etch rate on the surface having the (100) plane), the height or thickness portion of the feature is removed, while the lateral portion of the feature is substantially unchanged. Referring to FIGS. 2A-2C, with a low etch rate ratio, the surfaces 204, 212, 220 are removed at a slower rate than the surfaces 202, 208, 216. The surfaces having the (111) plane, such as surfaces 210, 218, have the slowest etch rate compared to the surfaces having the (110) or (110) plane. The etch selectivity between the surface having the (110) plane and the surface having the (100) plane, or the etch rate ratio of the surface having the (110) plane to the surface having the (100) plane, can be adjusted by varying the pressure within the processing chamber, the ratio of the flow rate of the etchant or gas mixture to the flow rate of the carrier gas, and/or the ratio of the flow rate of the etch enhancer or suppressor to the flow rate of the etchant.

In one embodiment, the etchant and the carrier gas are introduced into the processing chamber. The etchant is HCl and the carrier gas is hydrogen gas. A high etch rate ratio, such as over 5, can be achieved when the pressure inside the processing chamber is about 3 Torr, the ratio of the flow rate of the etchant to the flow rate of the carrier gas is about 0.06, and the temperature of the substrate is about 750 degrees Celsius. A low etch rate ratio, such as below 0.7, can be achieved when the pressure inside the processing chamber is about 300 Torr, the ratio of the flow rate of the etchant to the flow rate of the carrier gas is about 0.2, and the temperature of the substrate is about 700 degrees Celsius.

In another embodiment, the gas mixture including the etchant and the etch enhancer is introduced into the processing chamber along with the carrier gas. The etchant is HCl, the etch enhancer is GeH₄, and the carrier gas is hydrogen gas. A high etch rate ratio, such as over 2.4, can be achieved when the pressure inside the processing chamber is about 3 Torr, the ratio of the flow rate of the gas mixture to the flow rate of the carrier gas is about 0.22, the ratio of the flow rate of the etch enhancer to the flow rate of the etchant is about 0.01, and the temperature of the substrate is about 750 degrees Celsius. A low etch rate ratio, such as below 0.6, can be achieved when the pressure inside the processing chamber is about 200 Torr, the ratio of the flow rate of the gas mixture to the flow rate of the carrier gas is about 0.072, the ratio of the flow rate of the etch enhancer to the flow rate of the etchant is about 0.2, and the temperature of the substrate is about 700 degrees Celsius.

In another embodiment, the gas mixture including the etchant and the etch suppressor is introduced into the processing chamber along with the carrier gas. The etchant is HCl, the etch suppressor is silane, and the carrier gas is hydrogen gas. When an etch suppressor, such as a silicon containing gas, is introduced into the processing chamber along with the etchant and the carrier gas, the etch suppressor suppresses the etching of the surface having the (100) plane. Thus, the etch rate ratio is increased with the addition of the etch suppressor. The etch rate ratio may range from about 2 to about 75 when using the following process conditions. The temperature of the substrate is at 700 degrees Celsius or higher, such as about 750 degrees Celsius, and the pressure inside the processing chamber is about 5 Torr. The ratio of the flow rate of the gas mixture to the flow rate of the carrier gas ranges from about 0.14 to about 0.15, and the ratio of the flow rate of the etch suppressor to the flow rate of the etchant ranges from about 0.2 to about 0.25. In one embodiment, dichlorosilane is used instead of silane as the etch suppressor. Because dichlorosilane is a less reactive material than silane, the ratio of the flow rate of the dichlorosilane to the flow rate of the etchant ranges from about 1.0 to about 1.5. In another embodiment, disilane is used instead of silane as the etch suppressor. Because disilane is a more reactive material than silane, the ratio of the flow rate of the disilane to the flow rate of the etchant ranges from about 0.05 to about 0.06.

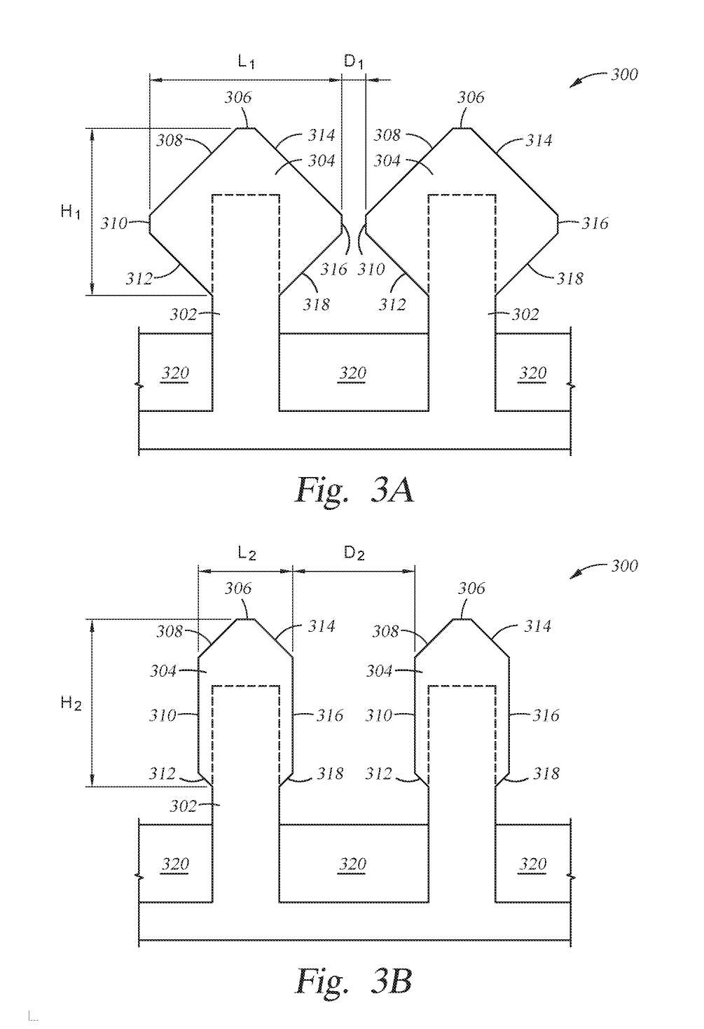

FIGS. 3A-3B illustrate a process for forming a semiconductor structure 300 according to one embodiment described herein. As shown in FIG. 3A, a plurality of semiconductor structures 300 (two are shown) may be formed on a substrate (not shown), and the plurality of semiconductor structures 300 becomes a plurality of transistors, such as FinFETs, after performing a series of process steps on the semiconductor structures. Each semiconductor structure 300 may include a semiconductor fin 302 and a stressor material 304 formed on the semiconductor fin 302. The semiconductor fin 302 may be made of silicon and the stressor material 304 may be made of Si, SiGe, SiGe:B, Si:P, Ge:P, or any other suitable semiconductor material. The stressor material 304 may include a first surface 306 having a (100) plane, a second surface 308 having a (111) plane, a third surface 310 having a (110) plane, a fourth surface 312 having a (111) plane, a fifth surface 314 having a (111) plane, a sixth surface 316 having a (110) plane, and a seventh surface 318 having a (111) plane. Each semiconductor structure 300 has a lateral dimension L1 and a height H1. The semiconductor structure 300 and an adjacent semiconductor structure 300 may be separated by a small distance D1. In other words, the surface 316 of the semiconductor structure 300 and the surface 310 of an adjacent semiconductor structure 300 is separated by a small distance D1. Shallow trench isolation (STI) regions 320 may be located between adjacent semiconductor fins 302. STI regions may be made of a dielectric material, such as SiO, SiN, SiCN, or any suitable dielectric material.

In order to increase the distance between adjacent semiconductor structures 300, the method 100 described in FIG. 1 with high etch rate ratio is performed on the semiconductor structures 300. High etch rate ratio means higher etch rate on the surface having the (110) plane than the etch rate on the surface having the (100) plane. Thus, the surfaces having (110) plane, such as surfaces 310, 316, are etched at a faster rate than the surfaces having the (100) plane, such as surface 306. The surfaces having (111) planes, such as surfaces 308, 312, 314, 318, have the slowest etch rate compared to the surfaces having (110) or (100) plane. As a result of performing the method 100 with high etch rate ratio on the semiconductor structures 300, the lateral dimension L1 of the semiconductor structure 300 is reduced significantly while the height H1 of the semiconductor structure 300 is substantially unchanged. As shown in FIG. 3B, the lateral dimension L2 is much smaller than the lateral dimension L1 shown in FIG. 3A, while the height H2 is substantially unchanged compared to the height H1 shown in FIG. 3A. The surfaces 310, 316 are removed at the fastest rate due to the high etch rate ratio of the surface having the (110) plane to the surface having the (100) plane. The etching of the surface 306 having the (100) plane may be suppressed with the addition of the etch suppressor as described in FIG. 1. With a smaller lateral dimension L2, the distance D2 between adjacent semiconductor structures 300 is greater than the distance D1 shown in FIG. 3A.

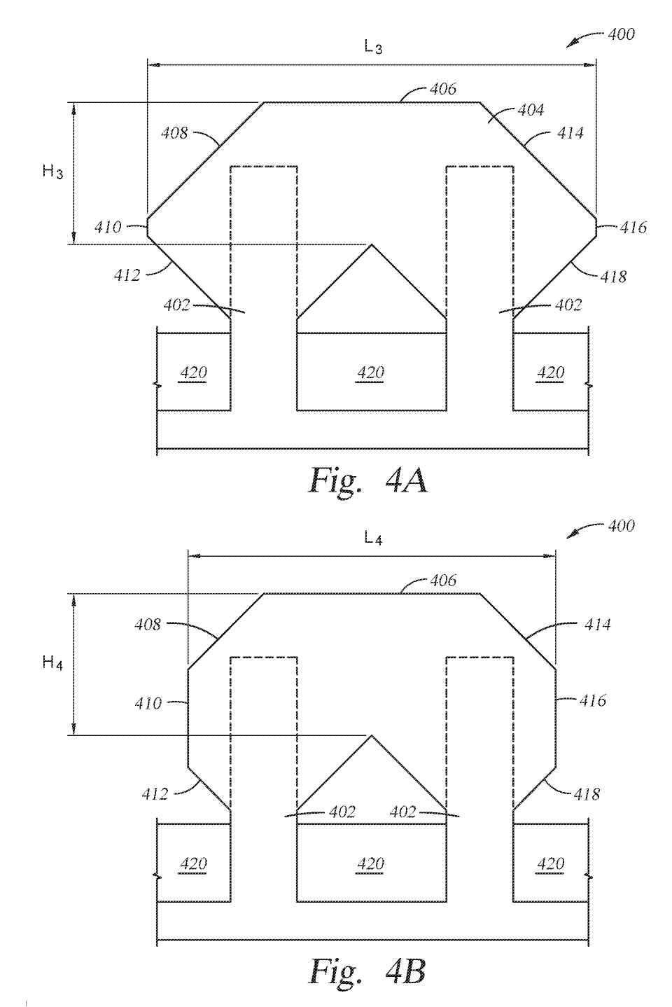

FIGS. 4A-4B illustrate a process for forming a semiconductor structure 300 according to one embodiment described herein. As shown in FIG. 4A, one or more semiconductor structures 400 (one is shown) may be formed on a substrate (not shown), and the semiconductor structures 400 become transistors, such as FinFETs, after performing a series of process steps on the semiconductor structures. Each semiconductor structure 400 may include two or more semiconductor fins 402 and a stressor material 404 formed on the semiconductor fins 402. The semiconductor fins 402 may be made of silicon and the stressor material 404 may be made of Si, SiGe, SiGe:B, Si:P, Ge:P, or any other suitable semiconductor material. The stressor material 404 may include a first surface 406 having a (100) plane, a second surface 408 having a (111) plane, a third surface 410 having a (110) plane, a fourth surface 412 having a (111) plane, a fifth surface 414 having a (111) plane, a sixth surface 416 having a (110) plane, and a seventh surface 418 having a (111) plane. The semiconductor structure 400 has a lateral dimension L3 and a height H3. Shallow trench isolation (STI) regions 420 may be located between adjacent semiconductor fins 402. STI regions may be made of a dielectric material, such as SiO, SiN, SiCN, or any suitable dielectric material.

In order to increase the distance between adjacent semiconductor structures 400, the method 100 described in FIG. 1 with high etch rate ratio is performed on the semiconductor structures 400. Thus, the surfaces having (110) plane, such as surfaces 410, 416, are etched at a faster rate than the surfaces having the (100) plane, such as surface 406. The surfaces having (111) planes, such as surfaces 408, 412, 414, 418, have the slowest etch rate compared to the surfaces having (110) or (100) plane. As a result of performing the method 100 with high etch rate ratio on the semiconductor structures 400, the lateral dimension L3 of the semiconductor structure 400 is reduced significantly while the height H3 of the semiconductor structure 400 is substantially unchanged. As shown in FIG. 4B, the lateral dimension L4 is much smaller than the lateral dimension L3 shown in FIG. 4A, while the height H4 is substantially unchanged compared to the height H3 shown in FIG. 4A. The surfaces 410, 416 are removed at the fastest rate due to the high etch rate ratio of the surface having the (110) plane to the surface having the (100) plane. The etching of the surface 406 having the (100) plane may be suppressed with the addition of the etch suppressor as described in FIG. 1. With a smaller lateral dimension L4, the distance between adjacent semiconductor structures 400 is increased.

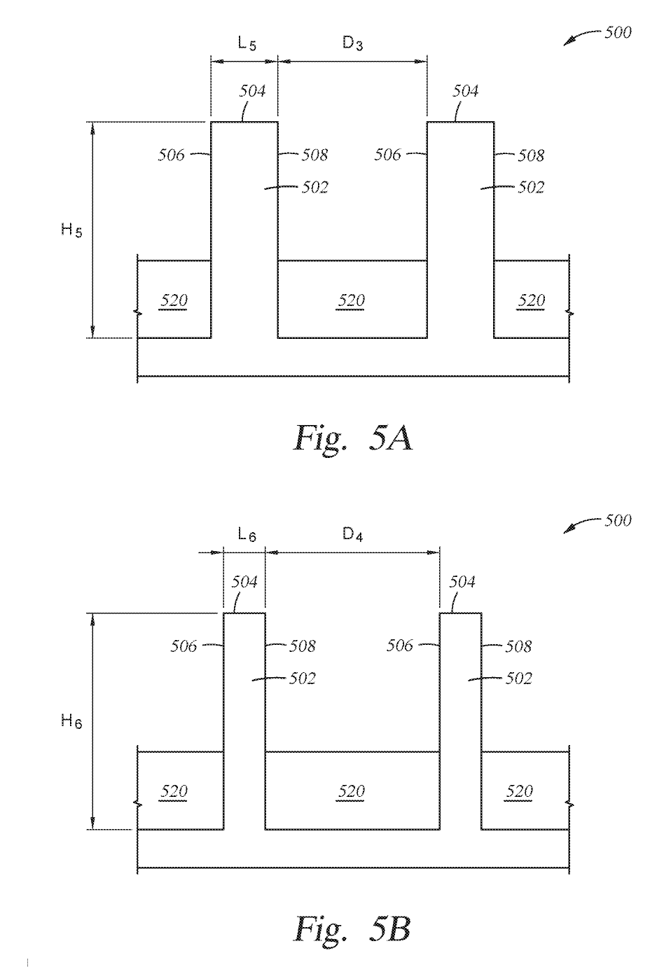

FIGS. 5A-5B illustrate a process for forming a semiconductor structure 500 according to one embodiment described herein. As shown in FIG. 3A, the semiconductor structure 500 includes a plurality of semiconductor fins 502. The semiconductor structure 500 becomes a plurality of transistors, such as FinFETs, after performing a series of process steps on the semiconductor structure 500. The semiconductor fin 502 may be made of silicon and may be formed by an epitaxial deposition process. Each semiconductor fin 502 may include a first surface 504 having a (100) plane, a second surface 506 having a (110) plane, and a third surface 508 having a (110) plane. Each semiconductor fin 502 has a lateral dimension L5 and a height H5. The semiconductor fin 502 and an adjacent semiconductor fin 502 may be separated by a distance D3. In other words, the surface 508 of the semiconductor fin 502 and the surface 506 of an adjacent semiconductor fin 502 is separated by a the distance D3. Shallow trench isolation (STI) regions 520 may be located between adjacent semiconductor fins 502. STI regions may be made of a dielectric material, such as SiO, SiN, SiCN, or any suitable dielectric material.

Stressor material or other suitable materials may be deposited on the semiconductor fins 502. With the distance D3 between adjacent semiconductor fins 502, the materials deposited on the adjacent semiconductor fins 502 may be too close to each other. One way to increase the distance between the materials deposited on adjacent semiconductor fins 502 is to increase the distance D3 between adjacent semiconductor fins 502. In order to increase the distance D3 between adjacent semiconductor fins 502, the method 100 described in FIG. 1 with high etch rate ratio is performed on the semiconductor fins 502. Thus, the surfaces having (110) plane, such as surfaces 506, 508, are etched at a faster rate than the surfaces having the (100) plane, such as surface 504. As a result of performing the method 100 with high etch rate ratio on the semiconductor fins 502, the lateral dimension L5 of the semiconductor fin 502 is reduced significantly while the height H5 of the semiconductor fin 502 is substantially unchanged. As shown in FIG. 5B, the lateral dimension L6 is much smaller than the lateral dimension L5 shown in FIG. 5A, while the height H6 is substantially unchanged compared to the height H5 shown in FIG. 5A. The surfaces 506, 508 are removed at the fastest rate due to the high etch rate ratio of the surface having the (110) plane to the surface having the (100) plane. The etching of the surface 504 having the (100) plane may be suppressed with the addition of the etch suppressor as described in FIG. 1. With a smaller lateral dimension L6, the distance D4 between adjacent semiconductor fins 502 is greater than the distance D3 shown in FIG. 5A, and the distance between materials deposited on adjacent semiconductor fins 502 is also increased.

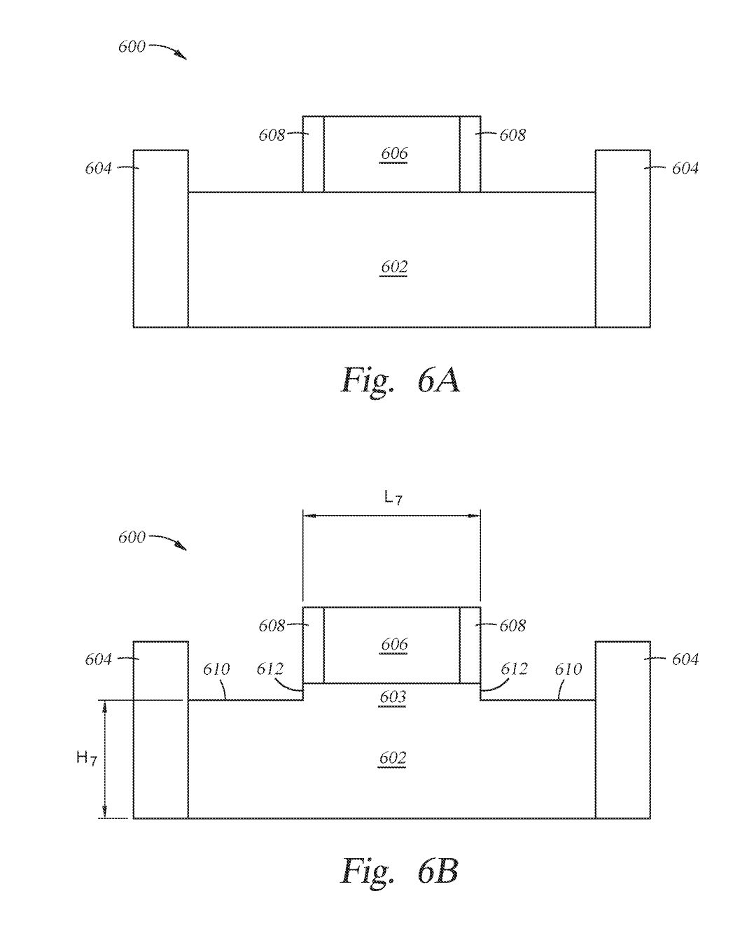

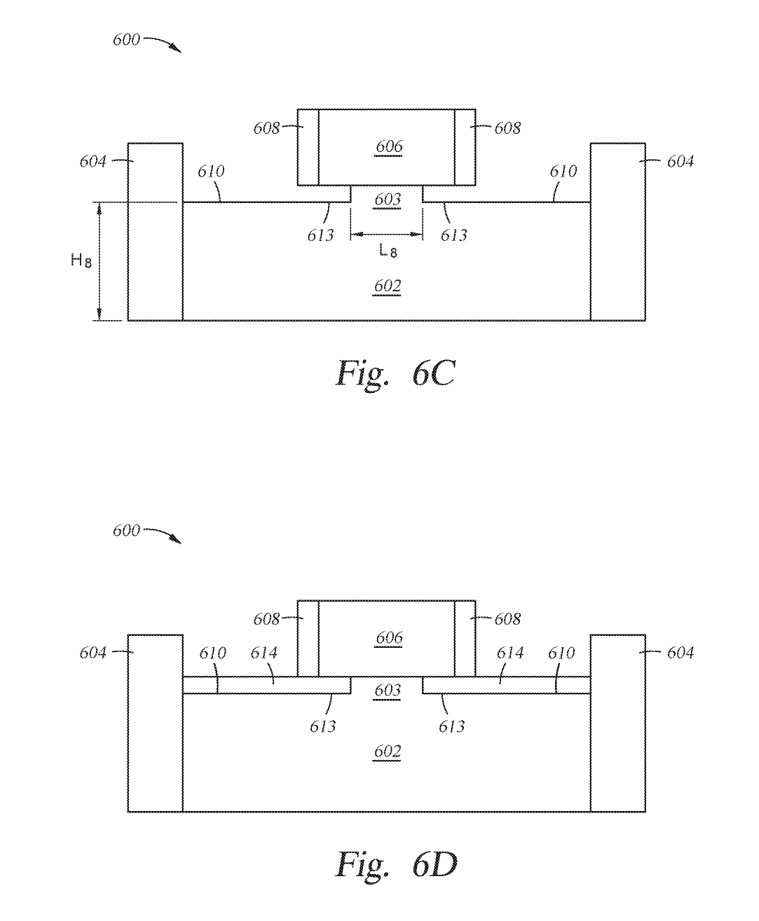

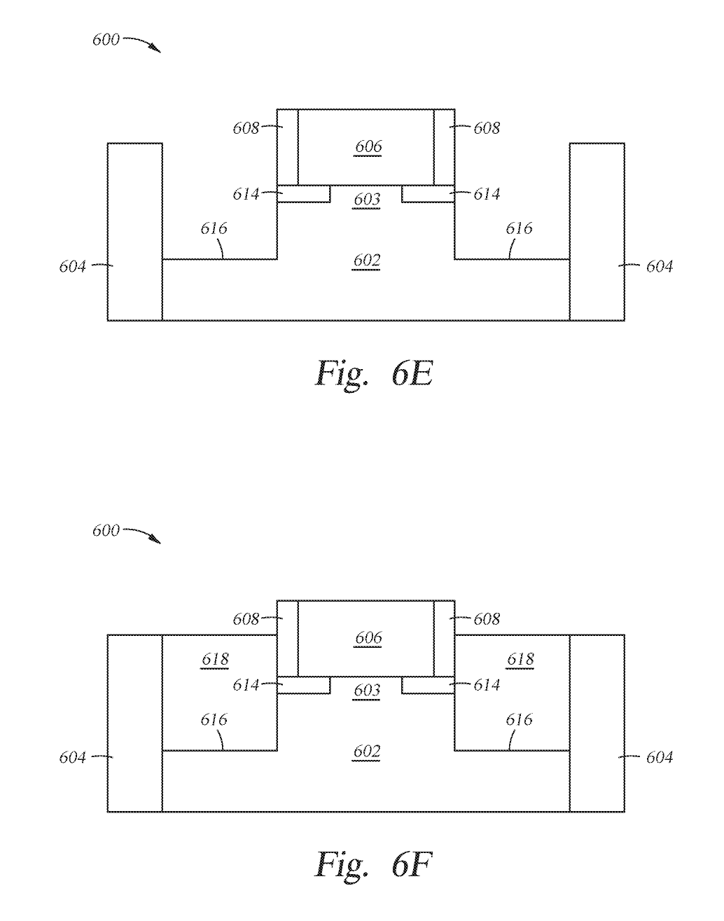

FIGS. 6A-6F illustrate a process for forming a semiconductor structure 600 according to one embodiment described herein. As shown in FIG. 6A, the semiconductor structure 600 includes a layer 602 located between two layers 604, and a gate stack 606 may be formed on the layer 602. The gate stack 606 may be located between two spacers 608, and the gate stack 606 and the spacers 608 may be located on a portion 603 of the layer 602. The semiconductor structure 600 becomes a transistor after performing a series of process steps on the semiconductor structure 600. The layer 602 may be made of silicon and may be formed by an epitaxial deposition process. The layers 604 may be the STI regions and may be made of a dielectric material, such as SiO, SiN, SiCN, or any suitable dielectric material. The gate stack 606 may include a gate layer and a gate dielectric.

Portions of the layer 602 not covered by the gate stack 606 and the spacers 608 are removed, exposing first surfaces 610 having a (100) plane and second surfaces 612 having a (110) plane, as shown in FIG. 6B. The portion 603 of the layer 602 covered by the gate stack 606 and the spacers 608 has a lateral dimension L7, and the layer 602 has a height H7.

In order to reduce the lateral dimension L7 without substantially changing the height H7, the method 100 described in FIG. 1 with high etch rate ratio is performed on the semiconductor structure 600. Thus, the surfaces having (110) plane, such as surfaces 612, are etched at a faster rate than the surfaces having the (100) plane, such as surfaces 610. As a result of performing the method 100 with high etch rate ratio on the semiconductor structure 600, the lateral dimension L7 of the portion 603 of the layer 602 is reduced significantly while the height H7 of the layer 602 is substantially unchanged. As shown in FIG. 6C, the lateral dimension L8 of the portion 603 is much smaller than the lateral dimension L7 shown in FIG. 6B, while the height H8 of the layer 602 is substantially unchanged compared to the height H7 shown in FIG. 6B. Surfaces 613 of the layer 602 disposed below the gate stack 606 and the spacers 608 are exposed, and the surfaces 613 may be planar with surfaces 610. The surfaces 612 are removed at the fastest rate due to the high etch rate ratio of the surface having the (110) plane to the surface having the (100) plane. The etching of the surfaces 610 having the (100) plane may be suppressed with the addition of the etch suppressor as described in FIG. 1.

As shown in FIG. 6D, a first material 614 may be deposited on the surfaces 610 and surfaces 613 below the gate stack 606 and the spacers 608, and the first material 614 may be a lightly doped semiconductor material. The first material 614 may be a conformal layer as shown in FIG. 6D, or may have a thicker portion that is not under the gate stack 606 and the spacers 608 compared to the portion that is under the gate stack 606 and the spacers 608. Portions of the first material 614 and the layer 602 not covered by the gate stack 606 and the spacers 608 are further removed, exposing third surfaces 616, as shown in FIG. 6E. A second material 618 may be deposited on the surfaces 616, as shown in FIG. 6F. The second material 618 may be the source or drain regions of a transistor, and the first material 616 may be the source or drain extension region.

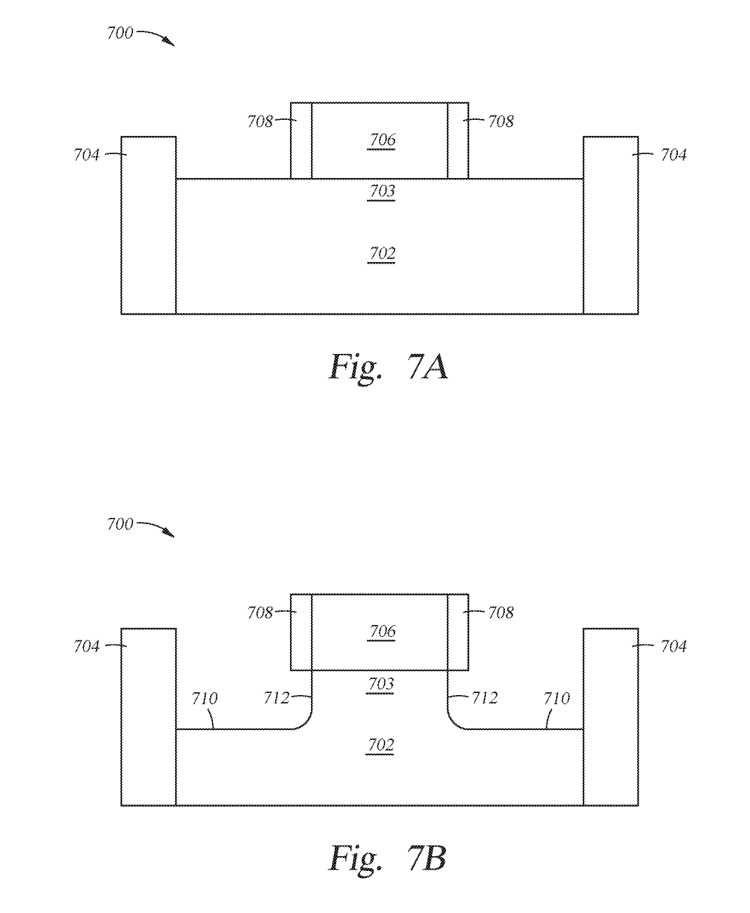

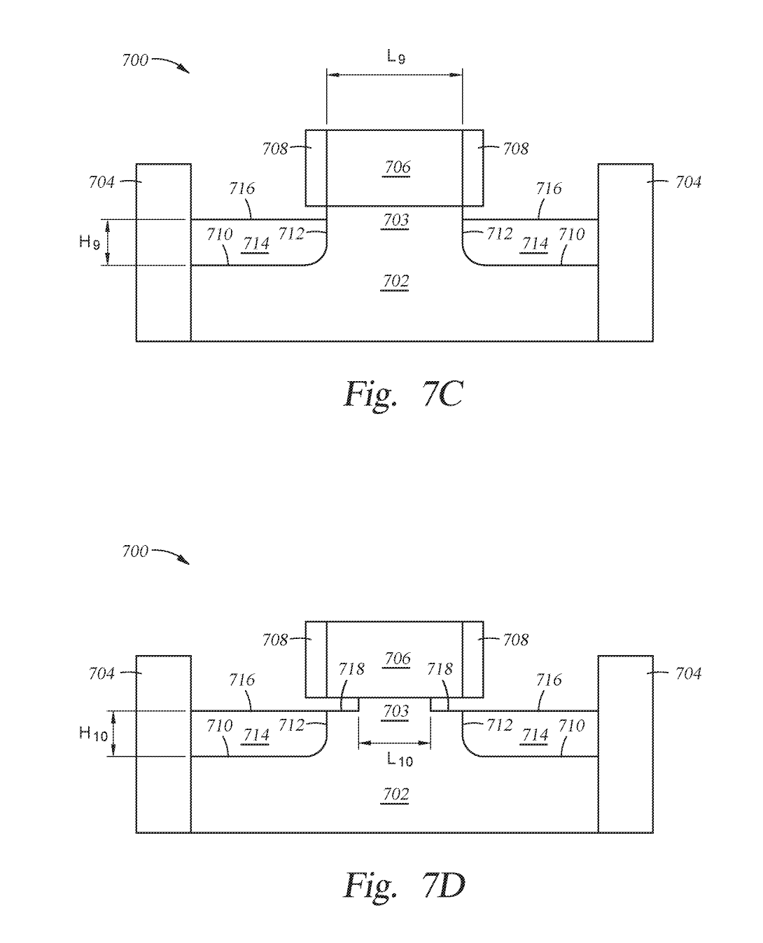

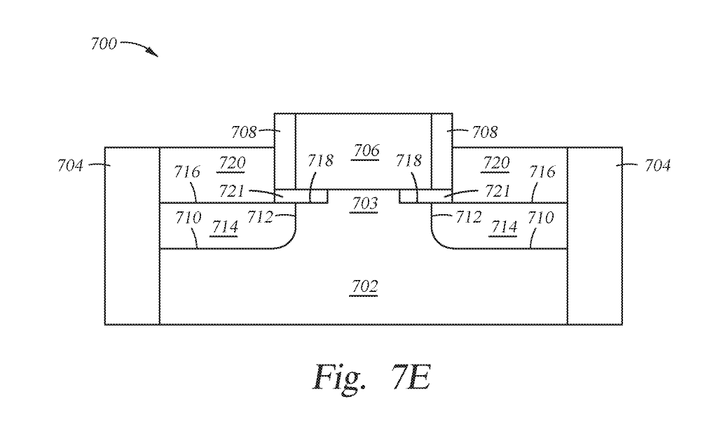

FIGS. 7A-7E illustrate a process for forming a semiconductor structure 700 according to one embodiment described herein. As shown in FIG. 7A, the semiconductor structure 700 includes a layer 702 located between two layers 704, and a gate stack 706 may be formed on the layer 702. The gate stack 706 may be located between two spacers 708, and the gate stack 706 and the spacers 708 may be located on a portion 703 of the layer 702. The semiconductor structure 700 becomes a transistor after performing a series of process steps on the semiconductor structure 700. The layer 702 may be made of silicon and may be formed by an epitaxial deposition process. The layers 704 may be the STI regions and may be made of a dielectric material, such as SiO, SiN, SiCN, or any suitable dielectric material. The gate stack 706 may include a gate layer and a gate dielectric.

Portions of the layer 702 not covered by the gate stack 606 are removed, exposing first surfaces 710 having a (100) plane and second surfaces 712 having a (110) plane, as shown in FIG. 7B. A first material 714 may be deposited on the surfaces 710 and may cover a portion of the second surfaces 712, as shown in FIG. 7C. The first material 714 may be deposited by an epitaxial deposition process. The first material 714 may be the same material as the material of the layer 702 or a different material than the material of the layer 702. The first material 714 may include a surface 716 having (100) plane. The portion 703 of the layer 702 covered by the gate stack 706 has a lateral dimension L9, and the first material 714 has a height H9.

In order to reduce the lateral dimension L9 without substantially changing the height H9, the method 100 described in FIG. 1 with high etch rate ratio is performed on the semiconductor structure 700. Thus, the surfaces having (110) plane, such as surfaces 712, are etched at a faster rate than the surfaces having the (100) plane, such as surfaces 716. As a result of performing the method 100 with high etch rate ratio on the semiconductor structure 700, the lateral dimension L9 of the portion 703 of the layer 702 is reduced significantly while the height H9 of the first material 714 is substantially unchanged. As shown in FIG. 7D, the lateral dimension L10 of the portion 703 is much smaller than the lateral dimension L9 shown in FIG. 7C, while the height H10 of the first material 714 is substantially unchanged compared to the height H9 shown in FIG. 7C. Surfaces 718 of the layer 702 disposed below the gate stack 706 are exposed, and the surfaces 718 may be planar with surfaces 716. The surfaces 712 are removed at the fastest rate due to the high etch rate ratio of the surface having the (110) plane to the surface having the (100) plane. The etching of the surfaces 716 having the (100) plane may be suppressed with the addition of the etch suppressor as described in FIG. 1.

As shown in FIG. 7E, a second material 721 may be deposited on the surfaces 718 below the gate stack 706 and on a portion of the surface 716 below the spacer 708. The second material 721 may be a lightly doped semiconductor material. A third material 720 may be deposited on the surfaces 716 not covered by the spacers 708. The third material 720 may be the source or drain regions of a transistor, and the second material 721 may be the source or drain extension region.

While the foregoing is directed to embodiments of the disclosure, other and further embodiments may be devised without departing from the basic scope thereof, and the scope thereof is determined by the claims that follow.

1. A method, comprising:
placing a substrate having a plurality of epitaxial features into a processing chamber, wherein each epitaxial feature of the plurality of epitaxial features has at least a surface having a (110) plane and a surface having a (100) plane;
heating the substrate to a temperature ranging from about 350 degrees Celsius to about 950 degrees Celsius;
introducing an etchant and a carrier gas into the processing chamber; and
selectively removing a portion of the epitaxial feature, wherein an etch selectivity between the surface having the (110) plane and the surface having the (100) plane is adjusted by varying a pressure within the processing chamber, and/or a ratio of a flow rate of the etchant to a flow rate of the carrier gas.

2. The method of claim 1, wherein the plurality of epitaxial features are made of silicon, silicon germanium, boron doped silicon germanium, phosphorus doped silicon, or phosphorus doped germanium.

3. The method of claim 1, wherein the etchant comprises a halogen containing gas.

4. The method of claim 3, wherein the etchant comprises HCl, Cl₂, HBr, PCl₃, GeCl₃, or BCl₃.

5. The method of claim 1, wherein the carrier gas comprises hydrogen gas or nitrogen gas.

6. The method of claim 1, wherein the ratio of the flow rate of the etchant to the flow rate of the carrier gas ranges from about 0.01 to about 0.22.

7. The method of claim 1, wherein the temperature of the substrate is about 600 degrees Celsius or higher.

8. A method, comprising:
placing a substrate having a plurality of epitaxial features into a processing chamber, wherein each epitaxial feature of the plurality of epitaxial features has at least a surface having a (110) plane and a surface having a (100) plane;
heating the substrate to a temperature ranging from about 350 degrees Celsius to about 950 degrees Celsius;
introducing a gas mixture and a carrier gas into the processing chamber, wherein the gas mixture includes an etchant and an etch enhancer or an etch suppressor; and
selectively removing a portion of the epitaxial feature, wherein an etch selectivity between the surface having the (110) plane and the surface having the (100) plane is adjusted by varying a pressure within the processing chamber, a ratio of a flow rate of the gas mixture to a flow rate of the carrier gas, and/or a ratio of a flow rate of the etch enhancer or suppressor to a flow rate of the etchant.

9. The method of claim 8, wherein the plurality of epitaxial features are made of silicon, silicon germanium, boron doped silicon germanium, phosphorus doped silicon, or phosphorus doped germanium.

10. The method of claim 8, wherein the etchant comprises HCl, Cl₂, HBr, PCl₃, GeCl₃, or BCl₃.

11. The method of claim 10, wherein the carrier gas comprises hydrogen gas or nitrogen gas.

12. The method of claim 11, wherein the etch suppressor comprises a silicon containing gas.

13. The method of claim 12, wherein the etch suppressor comprises silane, disilane, or dichlorosilane.

14. The method of claim 8, wherein the ratio of the flow rate of the gas mixture to the flow rate of the carrier gas ranges from about 0.01 to about 0.22.

15. The method of claim 8, wherein the temperature of the substrate is about 600 degrees Celsius or higher.

16. A method, comprising:
placing a substrate having a plurality of epitaxial features into a processing chamber, wherein each epitaxial feature of the plurality of epitaxial features has at least a surface having a (110) plane and a surface having a (100) plane;
heating the substrate to a temperature of about 600 degrees Celsius or higher;
introducing an etchant, a silicon containing gas, and a carrier gas into the processing chamber; and
selectively remove a lateral portion of the epitaxial feature, wherein a height of the epitaxial feature is substantially unchanged.

17. The method of claim 16, wherein the etchant comprises a halogen containing gas, the silicon containing gas comprises silane, disilane, or dichlorosilane, and the carrier gas comprises hydrogen gas or nitrogen gas.

18. The method of claim 17, wherein the silicon containing gas comprises silane, and the ratio of the flow rate of the silane to the flow rate of the etchant ranges from about 0.2 to about 0.25.

19. The method of claim 17, wherein the silicon containing gas comprises disilane, and the ratio of the flow rate of the disilane to the flow rate of the etchant ranges from about 0.05 to about 0.06.

20. The method of claim 17, wherein the silicon containing gas comprises dichlorosilane, and the ratio of the flow rate of the dichlorosilane to the flow rate of the etchant ranges from about 1.0 to about 1.5.
